(19) United States
(12) Patent Application Publication
(10) Pub. No.: US 2026/0156740 A1
(43) Pub. Date: Jun. 4, 2026

(54) ARRAY PRINTED CIRCUIT BOARD, AND PRINTED CIRCUIT BOARD AND MANUFACTURING METHOD OF THE SAME

(71) Applicant: Samsung Electronics Co., Ltd., Suwon-si (KR)

(72) Inventors: Jisook Han, Suwon-si (KR); Hyoungtaek Lim, Suwon-si (KR); Bongkyu Moon, Suwon-si (KR); Ho-Jin Chun, Suwon-si (KR); Jong-Wook Jeong, Suwon-si (KR)

(21) Appl. No.: 19/253,630

(22) Filed: Jun. 27, 2025

(30) Foreign Application Priority Data
Nov. 29, 2024 (KR) 10-2024-0175171

(51) Int. Cl. H05K 1/02; H05K 1/14; H05K 1/18

(52) U.S. Cl. CPC H05K 1/0296; H05K 1/142; H05K 1/181; H05K 2201/041

(57) ABSTRACT

An array printed circuit board includes a plurality of substrate regions in which a plurality of printed circuit boards are disposed, respectively, and a peripheral region connected to the plurality of substrate regions. At least one substrate region of the plurality of substrate regions comprises a separation hole. The at least one substrate region and the peripheral region comprise wiring, and the wiring comprises one or more wiring layers. The wiring comprises outer wiring that includes a first portion between an edge of the at least one substrate region and a first side of the separation hole that is adjacent to the edge of the at least one substrate region.

### CROSS-REFERENCE TO RELATED APPLICATION

This application claims priority to and the benefit of Korean Patent Application No. 10-2024-0175171, filed in the Korean Intellectual Property Office on Nov. 29, 2024, the entire contents of which are incorporated herein by reference.

### BACKGROUND

To improve productivity of a manufacturing process of a printed circuit board, an array printed circuit board including a plurality of printed circuit boards may be used. The array printed circuit board may include a plurality of regions in which a plurality of printed circuit boards are disposed, respectively, and a region configured to connect the plurality of printed circuit boards. The array printed circuit board may include wiring that connects the plurality of printed circuit boards for a test of the array printed circuit board.

After testing the array printed circuit board, the array printed circuit board may be cut into a printed circuit board. After cutting, the wiring that connects the plurality of printed circuit boards for the test of the array printed circuit board may be exposed on a side surface of the printed circuit board, which may cause a problem such as an electrical short circuit.

### SUMMARY

In general, the present disclosure is directed toward an array printed circuit board, a printed circuit board, and a manufacturing method of the same capable of improving reliability and productivity.

According to some implementations, the present disclosure is directed to an array printed circuit board that includes a plurality of substrate regions in which a plurality of printed circuit boards are disposed, respectively, and a peripheral region connected to the plurality of substrate regions. At least one substrate region of the plurality of substrate regions comprises a separation hole. The at least one substrate region and the peripheral region comprise wiring, and the wiring comprises one or more wiring layers. The wiring comprises outer wiring that includes a first portion between an edge of the at least one substrate region and a first side of the separation hole that is adjacent to the edge of the at least one substrate region.

According to some implementations, the present disclosure is directed to a printed circuit board that includes a stacking structure and a separation hole. The stacking structure includes an insulation layer and wiring, and the wiring comprises a plurality of wiring layers. The separation hole is configured to separate at least one wiring layer of the plurality of wiring layers. The wiring comprises dummy wiring between an edge of the stacking structure and a first side of the separation hole adjacent to the edge of the stacking structure.

In some implementations, the present disclosure is directed to a manufacturing method of a printed circuit board that includes forming an array printed circuit board, testing the array printed circuit board, forming a separation hole, and cutting the array printed circuit board. In the forming of the array printed circuit board, the array printed circuit board comprises a plurality of substrate regions in which a plurality of printed circuit boards are disposed, respectively, a peripheral region configured to connect the plurality of substrate regions, a test pad in the peripheral region, and connection wiring that electrically connects the test pad and at least one substrate region of the plurality of substrate regions. In the testing of the array printed circuit board, the array printed circuit board is tested using the test pad and the connection wiring. The separation hole is configured to disconnect the connection wiring from wiring in the at least one substrate region.

According to some implementations, the present disclosure is directed to wiring that is exposed on a side surface of a printed circuit board may be separated from wiring disposed in an inner region of the printed circuit board. Accordingly, when the printed circuit board is mounted on a jig or a bracket of an external electronic device, an undesirable electrical short that may be induced by the wiring that is exposed on the side surface of the printed circuit board may be prevented. Thereby, reliability of the printed circuit board may be improved.

According to some implementations, the present disclosure is directed to a portion of the wiring that is exposed on the side surface of the printed circuit board may be separated from a portion of the wiring that is disposed in the inner region of the printed circuit board by an easy process. Accordingly, productivity of the printed circuit board having improved reliability may be improved.

### BRIEF DESCRIPTION OF THE DRAWINGS

Example implementations will be more clearly understood from the following detailed explanation, taken in conjunction with the accompanying drawings.

FIG. 1 is a plan view showing an example of an array printed circuit board according to some implementations.

FIG. 2 is a cross-sectional view taken along a line A-A′ in FIG. 1 according to some implementations.

FIG. 3 is an enlarged plan view of a portion B in FIG. 1 according to some implementations.

FIG. 4 is a cross-sectional view taken along a line C-C′ in FIG. 3 according to some implementations.

FIG. 5 is a plan view showing an example a printed circuit board according to some implementations.

FIG. 6 is a cross-sectional view take along a line of E-E′ in FIG. 5 according to some implementations.

FIG. 7 to FIG. 9 are plan views showing an example of a manufacturing method of a printed circuit board according to some implementations.

FIG. 10 to FIG. 12 are cross-sectional views showing an example of a manufacturing method of a printed circuit board according to some implementations.

FIG. 13 to FIG. 15 are plan views showing an example of a manufacturing method of a printed circuit board according to some implementations.

FIG. 16 is a partial plan view showing an example of an array printed circuit board according to some implementations.

### DETAILED DESCRIPTION

Hereinafter, example implementations will be explained in detail with reference of the accompanying drawings.

A portion unrelated to the description is omitted in order to clearly describe the present disclosure, and same or similar components are denoted by a same reference numeral throughout the present disclosure.

Further, since a size and/or a thickness of a portion, a region, a member, a unit, a layer, a film, a substrate, or the like illustrated in the accompanying drawings may be arbitrarily illustrated for better understanding and convenience of explanation, the present disclosure is not limited to the illustrated size and/or thickness. In the drawings, a thickness of a portion, a region, a member, a unit, a layer, a film, a substrate, or the like may be enlarged or exaggerated for convenience of explanation and/or simple illustration.

It will be understood that when a component, such as a portion, a region, a member, a unit, a layer, a film, a substrate, or the like, is referred to as being “on” another component, it may be directly on another component or an intervening component may also be present. In contrast, when a component is referred to as being “directly on” another component, there is no intervening component. Further, when a component is referred to as being “on” or “above” a reference component, a component may be disposed on or below the reference component, and does not necessarily be “on” or “above” the reference component toward an opposite direction of gravity.

In addition, throughout the present disclosure, unless explicitly described to the contrary, the word “comprise,” “include,” or “contain,” and variations, such as “comprises,” “comprising,” “includes,” “including,” “contains,” or “containing,” will be understood to imply the inclusion of other components rather than the exclusion of any other components.

Further, throughout the present disclosure, a phrase “on a plane,” “in a plane,” “on a plan view,” or “in a plan view” may indicate a case where a portion is viewed from above or a top portion, and a phrase “on a cross-section” or “in a cross-sectional view” may indicate a case where a cross-section taken along a vertical direction is viewed from a side.

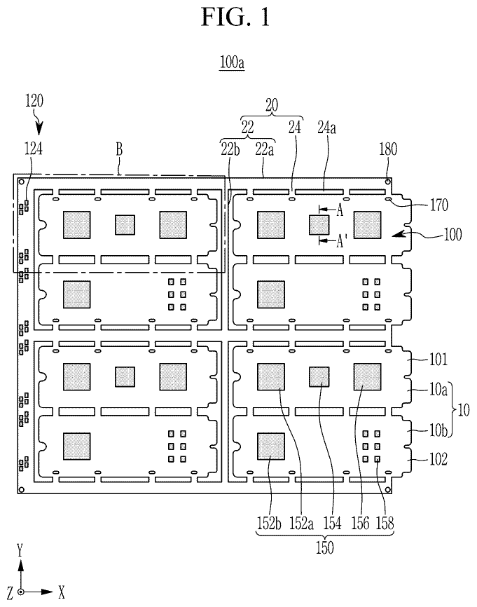

Hereinafter, referring to FIG. 1 to FIG. 6, an array printed circuit board 100a and a printed circuit board 100 according to some implementations will be described in detail.

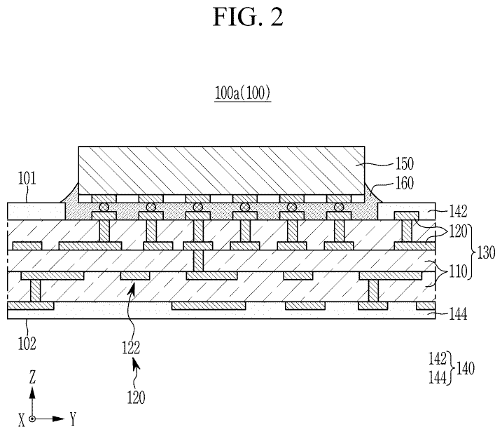

FIG. 1 is a plan view showing an example of an array printed circuit board 100a according to some implementations. FIG. 2 is a cross-sectional view taken along a line A-A′ in FIG. 1 according to some implementations.

In FIG. 1 and FIG. 2, an array printed circuit board 100a may include a plurality of substrate regions 10 and a peripheral region 20. In the plurality of substrate regions 10, a plurality of printed circuit boards 100 may be disposed, respectively. The peripheral region 20 may connect the substrate regions 10 or may be disposed near an edge of the substrate region 10.

After a cutting process of cutting the array printed circuit board 100a into an individual printed circuit board 100, at least a portion of the substrate region 10 may form the printed circuit board 100. In the substrate region 10, an electronic element 150 and wiring 120 (e.g., circuit wiring 122 or the like) that is electrically connected to the electronic element 150 may be provided to correspond each printed circuit board 100.

The peripheral region 20 may be disposed near the edge of the substrate region 10 and be configured to connect the plurality of substrate regions 10 to be integral. The peripheral region 20 may include a rail portion 22 and a bridge portion 24. The rail portion 22 may longitudinally extend along the edge of the substrate region 10. The bridge portion 24 may connect the rail portion 22 and the substrate region 10 or may be disposed between two adjacent substrate regions 10. For example, the bridge portion 24 may include a plurality of bridge portions 24 that are spaced apart from each other while interposing the through hole 24a.

In some implementations, the rail portion 22 may include a first rail portion 22a and a second rail portion 22b. The first rail portion 22a may extend in a first direction (an X-axis direction in the drawings) (e.g., a long-axis direction), and a second rail portion 22b may extend in a second direction (a Y-axis direction in the drawings) (e.g., a short-axis direction) that intersects (e.g., is perpendicular to) the first direction. The first rail portion 22a may be disposed outside the substrate region 10 or be disposed between the plurality of substrate regions 10. The second rail portion 22b may be disposed outside the substrate region 10 or be disposed between the plurality of substrate regions 10.

In FIG. 1, the bridge portion 24 is disposed between an edge (e.g., a long edge) of the substrate region 10 and the first rail portion 22a extending in the first direction (the X-axis direction in the drawings) of the long-axis direction, and/or between edges (e.g., lone edges) of the substrate regions 10 extending in the first direction of the long-axis direction. In FIG. 1, the bridge portion 24 is connected to the first rail portion 22a that extends in the first direction of the long-axis direction, and is not connected to the second rail portion 22b that extends in the second direction of the short-axis direction. Thereby, a stability may be improved and a structure may be simplified. However, the present disclosure is not limited thereto. In some implementations, the bridge portion 24 may be connected to at least one of a long edge and a short edge of the substrate region 10, and one or a plurality of bridge portions 24 may be connected to one edge. Unlike the above description, in some implementations, the bridge portion 24 may be connected to the short edge of the substrate region 10 and may not be connected to the long edge of the substrate region 10.

In FIG. 1, the first rail portion 22a is disposed between a pair of substrate regions 10 and another pair of substrate regions 10 in the second direction (the Y-axis direction in the drawings). That is, the first rail portion 22a may not be provided and the bridge portion 24 may be provided between a first substrate region 10a and a second substrate region 10b forming the pair of substrate regions 10. In FIG. 1, the second rail portion 22b is disposed on a first side (a left side in FIG. 1) of the substrate region 10 in the first direction (the X-axis direction in the drawings) and is not disposed on a second side (a right side in FIG. 1) of the substrate region 10 in the first direction. However, the present disclosure is not limited thereto, and a shape, a position, an arrangement, or the like of the first rail portion 22a or the second rail portion 22b may be variously modified.

The through hole 24a that is disposed between the bridge portions 24 may pass through the array printed circuit board 100a, and may have a shape that extends along the edge of the substrate region 10. Thereby, time and difficulty of the cutting process of cutting the array printed circuit board 100a into the individual printed circuit board 100 may be reduced and lowered, and damage of the printed circuit board 100 in the cutting process may be prevented or minimized. In FIG. 1, the through hole 24a includes a plurality of through holes 24a corresponding to one edge of the substrate region 10 in the first direction (the X-axis direction in the drawings) of the long-axis direction, and the through hole 24a extends to entirely correspond to one edge of the substrate region 10 in the second direction (the Y-axis direction in the drawings) of the short-axis direction. However, the present disclosure is not limited thereto, and a shape, a position, an arrangement, or the like of the through hole 24a may be variously modified.

In the peripheral region 20, a guide hole 180 configured to fix the array printed circuit board 100a to a desired position or a manufacturing apparatus in a manufacturing process may be provided. In FIG. 1, each guide hole 180 is adjacent to a corner portion and has a circular planar shape. However, the present disclosure is not limited to a number, a position, an arrangement, a shape, or the like of the guide hole 180.

Since the array printed circuit board 100a may include the plurality of substrate regions 10 as described in the above, productivity of a manufacturing process of the printed circuit board 100 may be improved. For example, a mounting process of a plurality of electronic elements 150 included in the printed circuit board 100 may be simplified. Further, a test of the plurality of printed circuit boards 100 included in the array printed circuit board 100a may be performed together in a test process of testing the array printed circuit board 100a, and process cost, process time, or the like may be reduced. After the test process of testing the array printed circuit board 100a, the peripheral region 20 may be cut in the cutting process to form the individual printed circuit board 100.

In FIG. 1, the array printed circuit board 100a includes eight substrate regions 10, but the present disclosure is not limited to a number of the substrate regions 10 included in the array printed circuit board 100a.

The array printed circuit board 100a may include a stacking structure 130 that includes an insulation layer 110 and wiring 120, and an electronic element 150 that is electrically connected to the wiring 120, and may further include a protection layer 140 and a molding portion 160. For example, the substrate region 10 or the printed circuit board 100 may include the insulation layer 110, the wiring 120, the protection layer 140, the electronic element 150, and the molding portion 160, and the peripheral region 20 may include the insulation layer 110, the wiring 120, and the protection layer 140.

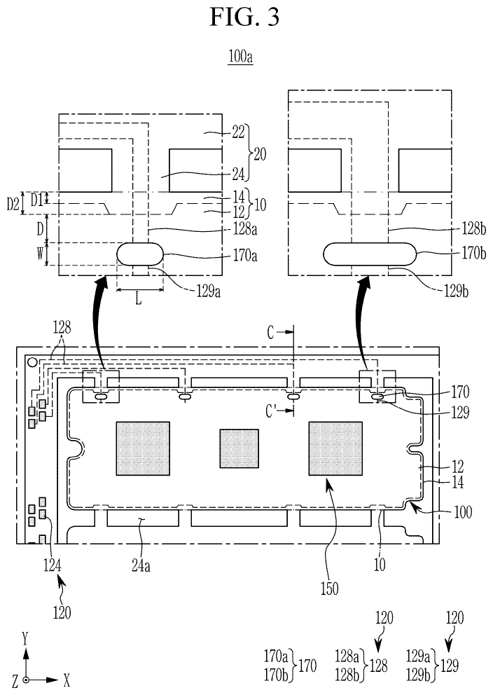

In some implementations, the wiring 120 may include a plurality of wiring layers and/or a contact via. The wiring 120 may include circuit wiring 122 that is disposed in the substrate region 10, a test pad 124 that is disposed in the peripheral region 20, and outer wiring 128 (refer to FIG. 3) and inner wiring 129 (refer to FIG. 3) that are spaced apart from the separation hole 170 in the substrate region 10.

The circuit wiring 122 may be disposed in the substrate region 10 to correspond to the printed circuit board 100 for an operation of the printed circuit board 100 or the electronic element 150 included in the printed circuit board 100. For example, the circuit wiring 122 may be disposed in a wiring region 12 (refer to FIG. 3) in the substrate region 10.

In the peripheral region 20 (e.g., the rail portion 22), a test pad 124 configured to test the array printed circuit board 100a may be provided. For example, the test pad 124 may be disposed on one side (a left side in FIG. 1) of the array printed circuit board 100a. One side of the array printed circuit board 100a on which the test pad 124 is disposed may be inserted into a test apparatus configured to perform the test process of the array printed circuit board 100a, and the array printed circuit board 100a and the test apparatus may be electrically connected to each other.

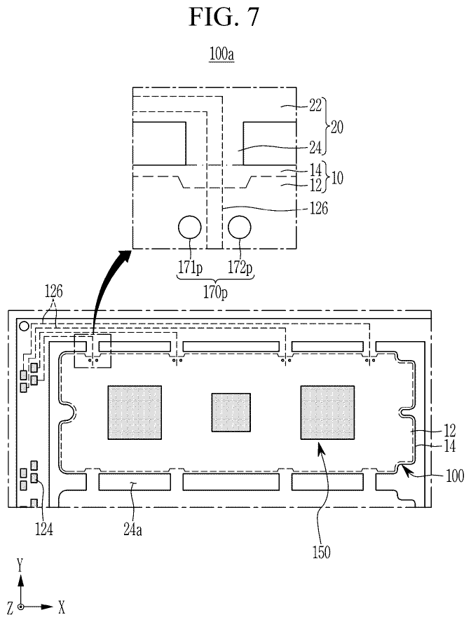

In the test process of the array printed circuit board 100a, the test pad 124 may receive a voltage or a signal from the test apparatus, and may supply the received voltage or signal to the substrate region 10 or the printed circuit board 100 through connection wiring 126 (refer to FIG. 7). For example, in the test process of the array printed circuit board 100a, the test pad 124 may be receive a power voltage, a ground voltage, and various signals for a test, and may supply the received voltages or signals to the substrate region 10 or the printed circuit board 100 through the connection wiring 126.

The connection wiring 126 may disposed in the substrate region 10 and the peripheral region 20, and may electrically connect the test pad 124 and the circuit wiring 122. After the test process, the separation hole 170 configured to disconnect the connection wiring 126 may be formed in the substrate region 10. Accordingly, in a final structure, the connection wiring 126 may remain in a form of the outer wiring 128 and the inner wiring 129 that are spaced apart from each other by the separation hole 170. The connection wiring 126, the outer wiring 128, and the inner wiring 129 will be described later in more detail.

The wiring 120 (e.g., the circuit wiring 122, the connection wiring 126, the outer wiring 128, or the inner wiring 129) may include or be formed of at least one of copper (Cu), aluminum (Al), silver (Ag), tin (Sn), gold (Au), nickel (Ni), lead (Pb), titanium (Ti), palladium (Pd), or an alloy including the same. However, the present disclosure is not limited to a material of the wiring 120.

The insulation layer 110 may be disposed between the plurality of wiring layers included in the wiring 120. The plurality of wiring layers included in the wiring 120 may be electrically insulated from each other by the insulation layer 110, and may be electrically connected to each other by the contact via that passes through the insulation layer 110 to form a predetermined electrical connection structure.

The insulation layer 110 may include or be formed of a thermosetting rein such as an epoxy resin, a thermoplastic resin such as polyimide, or prepreg formed by impregnating a resin into reinforced fibers. However, the present disclosure is not limited to a material of the insulation layer 110.

The protection layer 140 may be disposed on the stacking structure 130 that includes the insulation layer 110 and the wiring 120. The protection layer 140 may protect the stacking structure 130 in a portion other than a portion in which the electronic element 150, the test pad 124, or the like is disposed.

The protection layer 140 may include a first protection layer 142 and a second protection layer 144. The first protection layer 142 may be disposed on a first surface of the stacking structure 130. The second protection layer 144 may be disposed on a second surface of the stacking structure 130 opposite to the first surface of the stacking structure 130. The first protection layer 142 may be disposed on the first surface of the stacking structure 130 in a portion other than a portion for electrical connection of the test pad 124 and the electronic element 150. The second protection layer 144 may be disposed on the second surface of the stacking structure 130 in a portion other than a portion for electrical connection of the electronic element 150.

The protection layer 140 (e.g., the first protection layer 142 or the second protection layer 144) may include or be formed of a solder resist (e.g., a photo-imageable solder resist (PSR)). For example, the protection layer 140 may include or be formed of a thermosetting solder resist or the like. However, the present disclosure is not limited to a material of the protection layer 140.

The electronic element 150 may be mounted on the first surface of the stacking structure 130 and/or the second surface of the stacking structure 130. For example, electronic elements 150 may be mounted on a first surface 101 and a second surface 102 of the printed circuit board 100 opposite to each other. The first surface 101 of the printed circuit board 100 may refer to an outer surface of the first protection layer 142 that is adjacent to the first surface of the stacking structure 130, and the second surface 102 of the printed circuit board 100 may refer to an outer surface of the second protection layer 144 that is adjacent to the second surface of the stacking structure 130.

In some implementations, the electronic element 150 that is adjacent to the first surface 101 of the printed circuit board 100 may include a first memory element 152a, an active element 154, a logic element 156, or the like, and the electronic element 150 that is adjacent to the second surface 102 of the printed circuit board 100 may include a second memory element 152b, a passive element 158, or the like.

For example, the first memory element 152a or the second memory element 152b may include a non-volatile memory, such as a NAND flash memory system or the like, or a volatile memory, such as a dynamic random access memory (DRAM), a static random access memory (SRAM), or the like. The active element 154 may include a voltage regulator or the like. The logic element 156 may include a central processing unit (CPU), a neural processing unit (NPU), a micro controller unit (MCU), an application processor (AP), an application-specific integrated circuit (ASIC), or the like. The passive element 158 may include a resistor, an inductor, a capacitor, an RLC circuit, or the like. However, the present disclosure is not limited thereto, and a kind, a type, an arrangement, or the like of the electronic element 150 may be variously modified.

The molding portion 160 may be disposed between a side surface and/or a lower portion of the electronic element 150 and the stacking structure 130. The molding portion 160 may protect the electronic element 150 and a portion of the wiring 120 connected to the electronic element 150 and stably fix the electronic element 150. The molding portion 160 may include or be formed of an insulating material (e.g., a resin or the like). However, the present disclosure is not limited thereto, and a material of the molding portion 160 may be variously modified.

In some implementations, the substrate region 10 may include a first substrate region 10a and a second substrate region 10b. In the first substrate region 10a, the first surface 101 of the printed circuit board 100 may be disposed on an upper surface of the array printed circuit board 100a, and the second surface 102 of the printed circuit board 100 may be disposed on a lower surface of the array printed circuit board 100a. In the second substrate region 10b, the second surface 102 of the printed circuit board 100 may be disposed on the upper surface of the array printed circuit board 100a, and the first surface 101 of the printed circuit board 100 may be disposed at the lower surface of the array printed circuit board 100a. That is, in the array printed circuit board 100a, the first surface 101 of one printed circuit board 100 and the second surface 102 of another printed circuit board 100 may be disposed at a same surface. When the first substrate region 10a and the second substrate region 10b are included, productivity of the array printed circuit board 100a may be improved.

In FIG. 1, the first substrate region 10a and the second substrate region 10b are alternately disposed in the first direction (the X-axis direction in the drawings), and the first substrate region 10a and the second substrate region 10b are alternately disposed in the second direction (the Y-axis direction in the drawings). However, the present disclosure is not limited thereto. An arrangement of the first substrate region 10a and the second substrate region 10b may be variously modified. The first substrate region 10a and the second substrate region 10b may not be provided, and same surfaces of the printed circuit boards 100 may be disposed on a same surface in the plurality of substrate regions 10. Various other modified implementations are possible.

In FIG. 2, the wiring 120 included in the array printed circuit board 100a includes four wiring layers. However, the present disclosure are not limited thereto, and a number of the wiring layers of the wiring 120 included in the array printed circuit board 100a may be variously modified. For example, the wiring 120 included in the array printed circuit board 100a may include 2 or more (e.g., 20 or less) wiring layers.

In some implementations, the printed circuit board 100 that includes the electronic element 150 may be an electronic device, a semiconductor device, or a semiconductor package, or be included in an electronic device, a semiconductor device, or a semiconductor package. For example, the printed circuit board 100 may be a solid state drive or the like. However, the present disclosure is not limited thereto, and the printed circuit board 100 may be any of various electronic devices, semiconductor devices, or semiconductor packages, or be included in any of various electronic devices, semiconductor devices, or semiconductor packages.

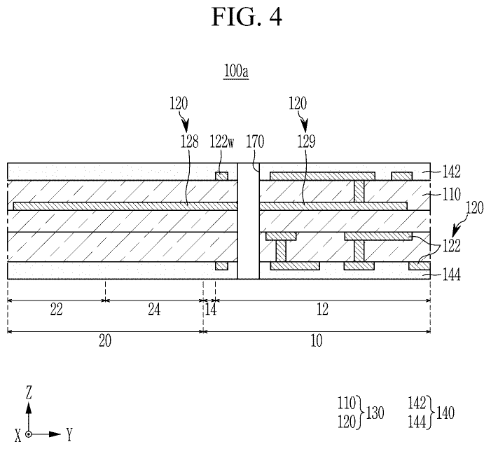

Referring to FIG. 3 and FIG. 4, the array printed circuit board 100a will be described in more detail.

FIG. 3 is an enlarged plan view of a portion B in FIG. 1 according to some implementations. FIG. 4 is a cross-sectional view taken along a line C-C′ in FIG. 3 according to some implementations. For a clear understanding and simple illustration, FIG. 3 conceptually illustrates the outer wiring 128 and the inner wiring 129 in portions of the peripheral region 20 and the substrate region 10.

In FIG. 3 and FIG. 4, the substrate region 10 may include a wiring region 12 and an edge region 14. In the wiring region 12, the circuit wiring 122 included in the printed circuit board 100 may be disposed. The edge region 14 may be disposed outside the wiring region 12. In the edge region 14, the circuit wiring 122 may not be disposed for an electrical stability. In the edge region 14, at least a portion of the connection wiring 126 (refer to FIG. 7) or the outer wiring 128 configured to test the array printed circuit board 100a may be disposed, and the wiring 120 other than the connection wiring 126 or the outer wiring 128 may not be disposed. That is, in the edge region 14, at least a portion of the connection wiring 126 or the outer wiring 128 may be disposed without the circuit wiring 122.

The wiring region 12 may be spaced apart from an edge of the substrate region 10 by a first distance D1 in a portion other than a portion connected to the bridge portion 24, and may be spaced apart from an edge of the substrate region 10 by a second distance D2 greater than the first distance D1 in the portion connected to the bridge portion 24. The first distance D1 or the second distance D2 may refer to a line width of the edge region 14, for example, a maximum line width of the edge region 14. The wiring region 12 may be spaced apart from the edge of the substrate region 10 by the relatively large second distance D2 in the portion connected to the bridge portion 24, thereby improving a stability in the cutting process. However, the present disclosure is not limited thereto, and the wiring region 12 may be spaced apart from the edge of the substrate region 10 with a uniform distance. Various other modified implementations are possible.

In some implementations, the outer wiring 128 and the inner wiring 129 that are spaced apart from each other while interposing the separation hole 170 may be formed of remained portions of the connection wiring 126 that electrically connected the test pad 124 and the circuit wiring 122 in the test process of the array printed circuit board 100a.

In some implementations, in the substrate region 10 (e.g., in the wiring region 12), the separation hole 170 may be disposed to separate at least one of the plurality of wiring layers disposed in the substrate region 10. For example, the separation hole 170 may separate the outer wiring 128 and the inner wiring 129. Since the separation hole 170 may be disposed in the wiring region 12, the circuit wiring 122 may include outside wiring 122w that is disposed outside the separation hole 170 in a plan view. For example, the outside wiring 122w may be disposed between an imaginary extension line that connects outer edges of the separation holes 170 and an edge of the wiring region 12.

In some implementations, the separation hole 170 may be configured to disconnect the connection wiring 126 and may separate the outer wiring 128 and the inner wiring 129 after the test process of the array printed circuit board 100a. The separation hole 170 may be referred to as a separation portion, a separation pattern, a separation through hole, an electrical separation hole, a physical separation hole, or the like.

The separation hole 170 may entirely pass through the array printed circuit board 100a, the printed circuit board 100, the substrate region 10, or the wiring region 12 in a thickness direction. Thereby, the separation hole 170 may be easily formed. However, the present disclosure is not limited thereto, and the separation hole 170 may partially pass through the array printed circuit board 100a, the printed circuit board 100, the substrate region 10, or the wiring region 12 in the thickness direction and disconnect the connection wiring 126. Various other modified implementations are possible.

The separation hole 170 may be disposed in the substrate region 10 (e.g., in the wiring region 12) and may be adjacent to the edge of the substrate region 10 (e.g., an edge of the wiring region 12). That is, a distance (e.g., a minimum distance) between the separation hole 170 and the edge of the substrate region 10 (e.g., the edge of the wiring region 12) may be less than a distance (e.g., a minimum distance) between the separation hole 170 and a center of the substrate region 10 (e.g., a center of the wiring region 12). Thereby, the separation hole 170 may be prevented from effecting an arrangement of the circuit wiring 122 disposed in the wiring region 12.

The outer wiring 128 may be disposed between the edge of the substrate region 10 and a first side (an upper side in an enlarged circle of FIG. 3) of the separation hole 170 that is adjacent to the edge of the substrate region 10, and be disposed in the bridge portion 24 and the rail portion 22. That is, the outer wiring 128 may include a first portion, a second portion, and a third portion. The first portion may be disposed between the edge of the substrate region 10 and the first side of the separation hole 170. The second portion may be disposed in the rail portion 22. The third portion may be disposed in the bridge portion 24 and connect the first portion and the second portion. For example, the first portion of the outer wiring 128 may include a portion disposed in the edge region 14 and a portion disposed in the wiring region 12. At least a portion (e.g., the first portion and/or the third portion) of the outer wiring 128 may extend to be parallel to an extension direction of the bridge portion 24. The extension direction of the bridge portion 24 may refer to a direction that intersects (e.g. is perpendicular to) the rail portion 22 to which the bridge portion 24 is connected.

The outer wiring 128 may be electrically insulated from another portion (e.g., the circuit wiring 122 or the inner wiring 129) of the wiring 120 disposed in the substrate region 10 (e.g., in the wiring region 12). For example, the outer wiring 128 may be electrically insulated from another portion (e.g., the circuit wiring 122 or the inner wiring 129) of the wiring 120 disposed in the substrate region 10 (e.g., in the wiring region 12) by the separation hole 170.

The inner wiring 129 may include a portion that extends to an inside of the substrate region 10 from the edge of the substrate region 10 or a second side of the separation hole 170 (a lower side in an enlarged circle of FIG. 3) opposite to the first side of the separation hole 170. That is, the inner wiring 129 may be disposed in the substrate region 10 (e.g., in the wiring region 12), and may be spaced apart from the first portion of the outer wiring 128 while interposing the separation hole 170. The inner wiring 129 may form a portion of the circuit wiring 122 disposed to correspond to the printed circuit board 100 for the operation of the electronic element 150, or may be electrically connected to the printed circuit board 100 for the operation of the electronic element 150.

The outer wiring 128 and the inner wiring 129 may be formed of the remained portions of the connection wiring 126 as described in the above, and the outer wiring 128 and the inner wiring 129 may be formed of portions of a layer formed by a same process. For example, the outer wiring 128 and the inner wiring 129 may include a same material, and may be disposed to correspond to each other on the first side and the second side of the separation hole 170. For example, the outer wiring 128 may include at least one outer wire element arranged on the first side of the separation hole 170 and the inner wiring 129 may include at least one inner wire element arranged on the second side of the separation hole 170, and the at least one outer wire element may be across from the at least one inner wire element, respectively. In a portion of the outer wiring 128 and a portion of the inner wiring 129 that face each other, the outer wiring 128 and the inner wiring 129 may have a same line width. The phrase that the outer wiring 128 and the inner wiring 129 are disposed to correspond to each other on the first side and the second side of the separation hole 170 may refer to that the outer wiring 128 and the inner wiring 129 are disposed at a same position in the first direction (the X-axis direction in the drawings) and/or that the outer wiring 128 and the inner wiring 129 are disposed to have a slight difference in the first direction. Having a same line width may refer to that a line width of the outer wiring 128 and a line width of the inner wiring 129 have a different within a process error (e.g., within 10%).

The separation hole 170 may separate and electrically insulate the outer wiring 128 and the inner wiring 129. The separation hole 170 may have a shape that extends in a direction parallel to an edge of the substrate region 10 or the wiring region 12 to which the separation hole 170 is adjacent. In some implementations, the separation hole 170 may have a shape extending in a direction that intersects (e.g. is perpendicular to) an extension direction of the first portion of the outer wiring 128 and/or the inner wiring 129. For example, the first portion of the outer wiring 128 and/or the inner wiring 129 may extend in the extension direction of the bridge portion 24, and the separation hole 170 may have a shape extending in a direction that intersects the extension direction of the bridge portion 24.

For example, a length L of the separation hole 170 may be greater than a width W of the separation hole 170. The width W of the separation hole 170 may refer to a width (e.g., a maximum width) of the separation hole 170 in an extension direction of the bridge portion 24, the first portion of the outer wiring 128, and/or the inner wiring 129. The length L of the separation hole 170 may refer to a length (e.g., a maximum length) of the separation hole 170 in the direction that intersects (e.g., is perpendicular to) the extension direction of the bridge portion 24, the first portion of the outer wiring 128, and/or the inner wiring 129. In some implementations, the length L of the separation hole 170 may refer to a length (e.g., a maximum length) of the separation hole 170 in a direction parallel to an edge of the substrate region 10 or the wiring region 12 to which the separation hole 170 is adjacent. Thereby, the outer wiring 128 and the inner wiring 129 may be stably separated.

The length L of the separation hole 170 may be same as or greater than a line width of the outer wiring 128 or the inner wiring 129. For example, the length L of the separation hole 170 may be greater than the line width of the outer wiring 128 or the inner wiring 129. Thereby, the separation hole 170 may entirely disconnect the outer wiring 128 and the inner wiring 129 and may stably separate the outer wiring 128 and the inner wiring 129. For example, a ratio of the length L of the separation hole 170 to the line width of the outer wiring 128 may be in a range of 1.2 to 3 (e.g., 1.2 to 2). In some implementations, a ratio of the length L of the separation hole 170 to the line width of the inner wiring 129 may be in a range of 1.2 to 3 (e.g., 1.2 to 2). When the ratio of the length L of the separation hole 170 to the line width of the outer wiring 128 or the ratio of the length L of the separation hole 170 to the line width of the inner wiring 129 is 1.2 or more, the separation hole 170 may stably disconnect the connection wiring 126. When the ratio of the length L of the separation hole 170 to the line width of the outer wiring 128 or the ratio of the length L of the separation hole 170 to the line width of the inner wiring 129 is 3.0 or less, the length L of the separation hole 170 may be prevented from being beyond a certain level.

However, the present disclosure is not limited thereto, and the ratio of the length L of the separation hole 170 to the line width of the outer wiring 128 or the ratio of the length L of the separation hole 170 to the line width of the inner wiring 129 may be less than 1.2 or greater than 3.

In FIG. 3, the separation hole 170 includes an inner portion and end portions. The inner portion may extend in the length direction of the separation hole 170 (in the first direction or the X-axis direction in the drawings) and may have a uniform width, and the end portions may be disposed at opposite sides of the inner portion in the length direction of the separation hole 170 and may have a rounded shape. Thereby, a structure stability may be improved, but the present disclosure is not limited thereto.

In a width direction of the separation hole 170 (in the second direction or the Y-axis direction in the drawings), the separation hole 170 may be spaced apart from the edge of the wiring region 12 by a separation distance D.

In some implementations, the width W of the separation hole 170 may be greater than the first distance D1, the second distance D2, or the separation distance D. Thereby, the separation hole 170 may have the width W sufficient to stably separate the outer wiring 128 and the inner wiring 129 of the connection wiring 126. In some implementations, the separation hole 170 may be formed using a drill (e.g., a router drill) used in the cutting process. Thereby, the process of forming the separation hole 170 may be simplified. However, the present disclosure is not limited thereto.

In some implementations, the width W of the separation hole 170 may be same as or less than the first distance D1, the second distance D2, or the separation distance D. Thereby, an area of the separation hole 170 may be reduced. In some implementations, the separation hole 170 may be formed by a laser cutting process. However, the present disclosure is not limited thereto.

In some implementations, the separation distance D may be greater than the first distance D1 or the second distance D2. Thereby, a process margin in a process of forming the separation hole 170 may be sufficient. However, the present disclosure is not limited thereto. In some implementations, the separation distance D may be same as or less than the first distance D1 or the second distance D2. Thereby, the separation hole 170 may be prevented from effecting an arrangement of the circuit wiring 122 disposed in the wiring region 12.

The connection wiring 126 may include a plurality of connection wirings 126 for the test process of the array printed circuit board 100a. The plurality of connection wirings may have different line widths. For example, the connection wiring 126 may include a first connection wiring that has a first line width and the second connection wiring that has a second line width greater than the first line width. Thereby, the outer wiring 128 may include a plurality of outer wirings that have different line widths, and the inner wiring 129 may include a plurality of inner wirings that have different line widths and correspond to the plurality of outer wirings, respectively. Accordingly, the separation hole 170 may include a plurality of separation holes (e.g., a first separation hole 170a and a second separation hole 170b) that have different lengths.

For example, a first outer wiring 128a and a first inner wiring 129a may be spaced apart from each other while interposing a first separation hole 170a, and a second outer wiring 128b and a second inner wiring 129b may be spaced apart from each other while interposing a second separation hole 170b. The first outer wiring 128a and the first inner wiring 129a may be formed of remained portions of the first connection wiring, and the second outer wiring 128b and the second inner wiring 129b may be formed of remained portions of the second connection wiring. A line width (e.g., the second line width) of the second outer wiring 128b may be greater than a line width 128a (e.g., the first line width) of the first outer wiring 128a, and a line width (e.g., the second line width) of the second inner wiring 129b may be greater than a line width (e.g., the first line width) of the first inner wiring 129a.

A length of the first separation hole 170a may be same as or greater than the first line width of the first outer wiring 128a or the first inner wiring 129a. For example, a ratio of the length of the first separation hole 170a to the first line width may be in a range of 1.2 to 3 (e.g., 1.2 to 2). A length of the second separation hole 170b may be same as or greater than the second line width of the second outer wiring 128b or the second inner wiring 129b. For example, a ratio of the length of the second separation hole 170b to the second line width may be in a range of 1.2 to 3 (e.g., 1.2 to 2). However, the present disclosure is not limited thereto.

In the present disclosure, it is described as an example that the plurality of separation holes 170 includes two separation holes (i.e., the first separation hole 170a and the second separation hole 170b) that have different lengths, but the present disclosure is not limited thereto. The plurality of separation holes 170 may have a same length, or may include three or more separation hole that have different lengths.

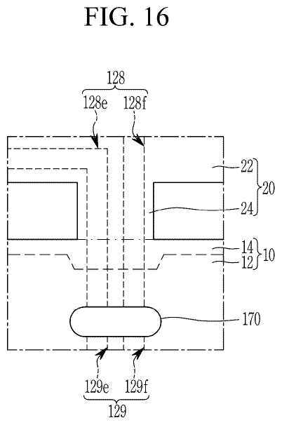

For simple illustration and a clear understanding, in FIG. 3, one outer wiring 128 and one inner wiring 129 are disposed in one bridge portion 24, but the present disclosure is not limited thereto. An implementation will be described later in detail with reference to FIG. 16.

In the drawings, an connection wiring 126 (in FIG. 7) or the outer wiring 128 electrically connect the test pad 124 and the substrate region 10 through the bridge portion 24 and the rail portion 22. Accordingly, the separation hole 170 may be disposed adjacent to the edge of the substrate region 10 that is adjacent to the bridge portion 24. In FIG. 3, the separation hole 170 is disposed adjacent to an upper edge of the substrate region 10, and is not disposed in portions adjacent to a lower edge, a left edge, and a right edge of the substrate region 10.

However, the present disclosure is not limited thereto. For example, the connection wiring 126 or the outer wiring 128 may be disposed in the bridge portion 24 that is connected to at least one of the long edge or the short edge of the substrate region 10, and the separation hole 170 may be disposed to e adjacent to the at least one of the long edge or the short edge of the substrate region 10 where the bridge portion 24 is disposed. In some implementations, the connection wiring 126 or the outer wiring 128 may be disposed in the bridge portion 24 that connects two substrate regions 10 (i.e., the first substrate region 10a (refer to FIG. 1) and the second substrate region 10b (refer to FIG. 1)), and the separation hole 170 may be disposed to e adjacent to the bridge portion 24 that connects the two substrate regions 10 (i.e., the first substrate region 10a and the second substrate region 10b). As such, a position of the separation hole 170 may be variously modified according to a position of the connection wiring 126 or the outer wiring 128.

The cutting process of the array printed circuit board 100a may be performed to separate the array printed circuit board 100a into the individual printed circuit board 100. Thereby, a plurality of printed circuit boards 100 may be formed.

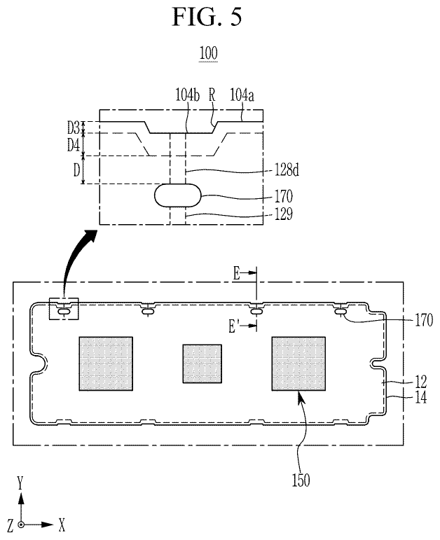

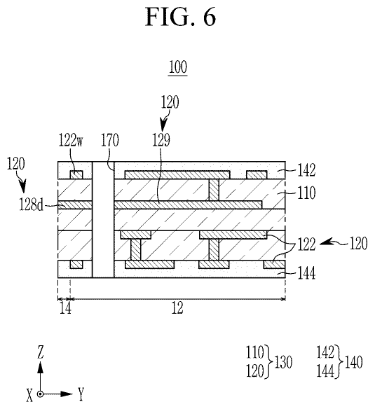

Referring to FIG. 5 and FIG. 6, a printed circuit board 100 according to some implementations will be described in detail.

FIG. 5 is a plan view showing an example of a printed circuit board 100 according to some implementations. FIG. 6 is a cross-sectional view take along a line of E-E′ in FIG. 5 according to some implementations. FIG. 5 illustrates a portion corresponding to FIG. 3, and FIG. 6 illustrates a portion corresponding to FIG. 4.

In FIG. 5 and FIG. 6, a cutting process may be performed. In the cutting process, the array printed circuit board 100a (refer to FIG. 3) may be cut in a bridge portion 24 (refer to FIG. 3) and a peripheral region 20 (refer to FIG. 3) may be removed. Thereby, the printed circuit board 100 may include at least a portion of a substrate region 10 (refer to FIG. 3).

In some implementations, the printed circuit board 100 or a stacking structure 130 included in the printed circuit board 100 may include a wiring region 12 and an edge region 14. In the wiring region 12, circuit wiring 122 included in the printed circuit board 100 may be disposed. The edge region 14 may be disposed outside the wiring region 12. In the edge region 14, at least a portion of dummy wiring 128d may be disposed without the circuit wiring 122.

Unless described otherwise, a description of an insulation layer 110, wiring 120, a stacking structure 130, a protection layer 140, an electronic element 150, and a molding portion 160 of an array printed circuit board 100a with reference to FIG. 1 to FIG. 4 may be applied to the printed circuit board 100.

In the cutting process of the array printed circuit board 100a, the array printed circuit board 100a may be cut so that the printed circuit board 100 has a recess portion R in a portion that was connected to the bridge portion 24. Accordingly, a second edge 104b of the printed circuit board 100 may be closer to an inside of the printed circuit board 100 than a first edge 104a of the printed circuit board 100. The first edge 104a of the printed circuit board 100 may be an edge of the printed circuit board 100 in a portion other than the portion that was connected to the bridge portion 24. The second edge 104b of the printed circuit board 100 may be an edge of the printed circuit board 100 in a portion that was connected to the bridge portion 24. Thereby, a problem that may be undesirably induced by a portion (e.g., the dummy wiring 128d) of the wiring 120 exposed on a side surface of the printed circuit board 100 may be effectively prevented.

For example, the second edge 104b of the printed circuit board 100 may be spaced apart from the first edge 104a of the printed circuit board 100 by a third distance D3, and the second edge 104b of the printed circuit board 100 may be spaced apart from an edge of the wiring region 12 by a fourth distance D4. The fourth distance D4 may be greater than the third distance D3. Thereby, the cutting process may be performed to be spaced apart from the wiring region 12 by the fourth distance D4 that is relatively large, thereby improving an electrical stability. However, the present disclosure is not limited thereto, and the fourth distance D4 may be same as or less than the third distance D3.

In some implementations, the wiring 120 (e.g., the dummy wiring 128d) exposed on the side surface of the printed circuit board 100 may be separated from the inner wiring 129, and a problem that may be induced by the wiring 120 (e.g., the dummy wiring 128d) exposed on the side surface of the printed circuit board 100 may be prevented. In some implementations, the cutting process may be performed so that the first edge 104a and the second edge 104b of the printed circuit board 100 are disposed on a same line. Thereby, the printed circuit board 100 may not include the recess portion R in the portion that was connected to the bridge portion 24.

In some implementations, in the printed circuit board 100 or the stacking structure 130 (e.g., in the wiring region 12), the separation hole 170 configured to separate the dummy wiring 128d and the inner wiring 129 may be disposed. The separation hole 170 may be disposed in the wiring region 12, and the circuit wiring 122 may include outside wiring 122w that is disposed outside the separation hole 170 in a plan view. By removing the peripheral region 20, a second portion and a third portion of outer wiring 128 (refer to FIG. 3) may be removed, and at least a portion of a first portion of the outer wiring 128 may remain to form the dummy wiring 128d.

Unless described otherwise, a description of the outer wiring 128 (e.g., the first portion of the outer wiring 128) of the array printed circuit board 100a may be applied to the dummy wiring 128d. Unless described otherwise, a description of the separation hole 170 and the inner wiring 129 of the array printed circuit board 100a may be applied to the separation hole 170 and the inner wiring 129 of the printed circuit board 100.

The separation hole 170 may be adjacent to an edge of the printed circuit board 100 (e.g., the stacking structure 130). For example, the separation hole 170 may be adjacent to an edge of the wiring region 12 in the wiring region 12.

The dummy wiring 128d may be disposed between an edge (e.g., the second edge 104b) of the printed circuit board 100 and a first side of the separation hole 170 (an upper side in an enlarged circle of FIG. 5) adjacent to the edge (e.g., the second edge 104b) of the printed circuit board 100. The dummy wiring 128d may include a portion disposed in the edge region 14 and a portion disposed in the wiring region 12. The dummy wiring 128d may extend in a direction that intersects (e.g. is perpendicular to) the edge (e.g., the second edge 104b) of the printed circuit board 100.

The dummy wiring 128d may be electrically insulated from another portion (e.g., the circuit wiring 122 or the inner wiring 129) of the wiring 120 disposed in the substrate region 10 (e.g., in the wiring region 12). For example, the outer wiring 128 may be electrically insulated from another portion (e.g., the circuit wiring 122 or the inner wiring 129) of the wiring 120 disposed in the substrate region 10 (e.g., in the wiring region 12) by the separation hole 170. The dummy wiring 128d may be referred to as a separated wiring, an electrically separated wiring, a separated pattern, an electrically separated pattern, or the like.

The inner wiring 129 may include a portion that extends to an inside of the wiring region 12 from the edge of the printed circuit board 100 (e.g., the stacking structure 130) or a second side of the separation hole 170 (a lower side in an enlarged circle of FIG. 5) opposite to the first side of the separation hole 170. That is, the inner wiring 129 may be disposed in the wiring region 12, and may be spaced apart from the dummy wiring 128d while interposing the separation hole 170.

In some implementations, the dummy wiring 128d and the inner wiring 129 may be formed of remained portions of connection wiring 126 (refer to FIG. 7), and the dummy wiring 128d and the inner wiring 129 may be formed of portions of a layer formed by a same process. For example, the dummy wiring 128d and the inner wiring 129 may include a same material, and may be disposed to correspond to each other on the first side and the second side of the separation hole 170. For example, the dummy wiring 128d may include at least one dummy wire element arranged on the first side of the separation hole 170 and the inner wiring 129 may include at least one inner wire element arranged on the second side of the separation hole 170, and the at least one dummy wire element may be across from the at least one inner wire element, respectively. In a portion of the dummy wiring 128d and a portion of the inner wiring 129 that face each other, the dummy wiring 128d and the inner wiring 129 may have a same line width. The phrase that the dummy wiring 128d and the inner wiring 129 are disposed to correspond to each other on the first side and the second side of the separation hole 170 may refer to that the dummy wiring 128d and the inner wiring 129 are disposed at a same position in a first direction (an X-axis direction in the drawings) and/or that the dummy wiring 128d and the inner wiring 129 are disposed to have a slight difference in the first direction. Having a same line width may refer to that a line width of the dummy wiring 128d and a line width of the inner wiring 129 have a different within a process error (e.g., within 10%).

The separation hole 170 may separate and electrically insulate the dummy wiring 128d and the inner wiring 129. The separation hole 170 may have a shape that extends in a direction parallel to the edge of the printed circuit board 100 (e.g., the stacking structure 130) to which the separation hole 170 is adjacent. In some implementations, the separation hole 170 may have a shape extending in a direction that intersects (e.g. is perpendicular to) an extension direction of the first portion of the dummy wiring 128d and/or the inner wiring 129.

For example, a length of the separation hole 170 may be greater than a width of the separation hole 170. In some implementations, the length of the separation hole 170 may be same as or greater than a line width of the dummy wiring 128d or extension direction of the inner wiring 129. For example, a ratio of the length of the separation hole 170 to the line width of the dummy wiring 128d may be in a range of 1.2 to 3 (e.g., 1.2 to 2). In some implementations, a ratio of the length of the separation hole 170 to the line width of the inner wiring 129 may be in a range of 1.2 to 3 (e.g., 1.2 to 2). However, the present disclosure is not limited thereto, and the ratio of the length of the separation hole 170 to the line width of the dummy wiring 128d or the ratio of the length of the separation hole 170 to the line width of the inner wiring 129 may be less than 1.2 or greater than 3.

In a width direction of the separation hole 170 (in a second direction or an Y-axis direction in the drawings), the separation hole 170 may be spaced apart from the edge of the wiring region 12 by a separation distance D.

In some implementations, the separation distance D may be greater than the third distance D3 or the fourth distance D4. Thereby, a process margin in a process of forming the separation hole 170 may be sufficient. However, the present disclosure is not limited thereto. In some implementations, the separation distance D may be same as or less than the third distance D3 or the fourth distance D4. Thereby, the separation hole 170 may be prevented from effecting an arrangement of the circuit wiring 122 disposed in the wiring region 12.

In some implementations, the dummy wiring 128d may include a plurality of dummy wirings that have different line widths, and the inner wiring 129 may include a plurality of inner wirings that have different line widths and correspond to the plurality of dummy wirings, respectively. Accordingly, the separation hole 170 may include a plurality of separation holes (e.g., a first separation hole 170a (refer to FIG. 3) and a second separation hole 170b (refer to FIG. 3)) that have different lengths. A description of a plurality of outer wiring, a plurality of inner wirings, and a plurality of separation holes with reference to FIG. 3 and FIG. 4 may be applied to the plurality of dummy wirings, the plurality of inner wirings, and the plurality of separation holes.

In some implementations, the outer wiring 128 that is exposed to the outside after the cutting process may be changed to the dummy wiring 128d that is electrically insulated from the circuit wiring 122 or the inner wiring 129 disposed in the wiring region 12.

According to some implementations, the wiring 120 (e.g., the dummy wiring 128d) that is exposed on the side surface of the printed circuit board 100 may be separated from the circuit wiring 122 or the inner wiring 129 disposed in an inner region of the printed circuit board 100 (e.g., in the wiring region 12). Accordingly, when the printed circuit board 100 is mounted on a jig or a bracket of an external electronic device, an undesirable electrical short that may be induced by the wiring 120 (e.g., the dummy wiring 128d) that is exposed on the side surface of the printed circuit board 100 may be prevented. Thereby, reliability of the printed circuit board 100 may be improved.

In a comparative example where wiring that is exposed on a side surface of a printed circuit board is electrically connected to wiring disposed in an inner region of the printed circuit board. When the printed circuit board is mounted on a jig or a bracket of an external electronic device, the wiring that is exposed on the side surface of the printed circuit board may be undesirably electrically connected to the external electronic device (e.g., ground of the external electronic device) and an electric short may be induced undesirably. If the side surface of the printed circuit board may be removed more to prevent the above problem, a region where the wiring is disposed may be undesirably reduced and the problem due to the wiring exposed on the side surface of the printed circuit board may exist.

Referring to FIG. 7 to FIG. 15, an example of a manufacturing method of a printed circuit board according to some implementations will be described in detail. To the extent that an element is not described in detail below, it may be understood that the element is at least similar to a corresponding element that has been described elsewhere within the present disclosure. A portion which is not described in the above will be described in detail.

FIG. 7 to FIG. 9 are plan views showing an example of a manufacturing method of a printed circuit board according to some implementations. FIG. 7 to FIG. 9 illustrate a portion corresponding to FIG. 3 or FIG. 5.

In FIG. 7 to FIG. 9, a manufacturing method of a printed circuit board 100 may include a process of forming an array printed circuit board 100a, a test process of the array printed circuit board 100a, and a process of forming a separation hole 170 and cutting the array printed circuit board 100a into an individual printed circuit board 100.

First, in FIG. 7, a process of forming an array printed circuit board 100a may be performed, and a test process of the array printed circuit board 100a may be performed.

In the process of forming the array printed circuit board 100a, the array printed circuit board 100a may be formed. The array printed circuit board 100a may include a plurality of substrate regions 10 in which a plurality of substrate regions 10 are disposed, respectively, a peripheral region 20 that connects the plurality of substrate regions 10, a test pad 12 that is disposed in the peripheral region 20, and connection wiring 126 that electrically connects the test pad 124 and the substrate region 10.

The connection wiring 126 may extend from the test pad 124 and extend to an inside of the substrate region 10 (e.g., an inside of the wiring region 12) through the bridge portion 24. The connection wiring 126 may include a plurality of connection wirings configured to transmit a power voltage, a ground voltage, and various signals for a test. For example, the connection wiring 126 may include a plurality of connection wirings that have different line widths. For example, the connection wiring 126 may include a first connection wiring that has a first line width and a second connection wiring that has a second line width greater than the first line width. However, the present disclosure is not limited thereto.

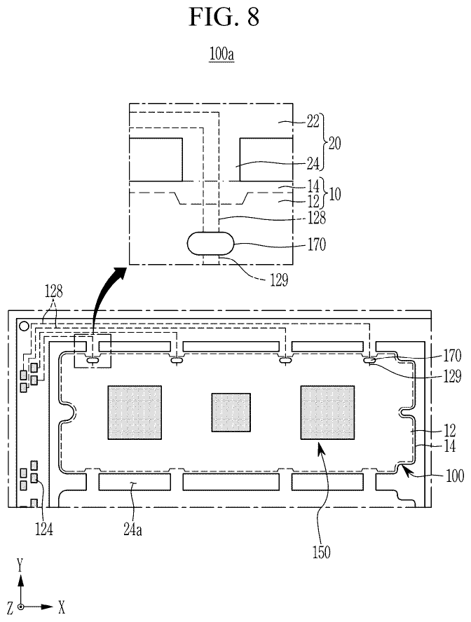

In some implementations, in the process of forming the array printed circuit board 100a, a preliminary mark may be formed in a portion corresponding to at least a portion of a separation hole 170 (refer to FIG. 8). For example, the array printed circuit board 100a may include a preliminary hole 170p as the preliminary mark. By the preliminary hole 170p, a position where the separation hole 170 will be disposed may be easily recognized or determined in a process of forming the separation hole 170. When the connection wiring 126 may be disposed in an inner portion of the array printed circuit board 100a, by marking the position of the separation hole 170 using the preliminary mark (e.g., the preliminary hole 170p), the position where the separation hole 170 will be disposed may be easily recognized or expected.

In some implementations, the preliminary hole 170p may include a first preliminary hole 171p and a second preliminary hole 172p disposed at opposite sides of the connection wiring 126. For example, the first preliminary hole 171p and the second preliminary hole 172p may be disposed to correspond to opposite ends of the separation hole 170. Thereby, in the process of forming the separation hole 170, the separation hole 170 may be formed to connect the first preliminary hole 171p and the second preliminary hole 172p. Thereby, the separation hole 170 may be easily formed. However, the present disclosure is not limited thereto, and the preliminary hole 170p may include at least one of the first preliminary hole 171p and the second preliminary hole 172p, or may further include an additional hole other than the first preliminary hole 171p and the second preliminary hole 172p.

The preliminary hole 170p may have a size (e.g., a diameter) same as or greater than a bit size (e.g., a bit diameter) of a drill (e.g., a router drill) used in a cutting process. However, the present disclosure is not limited thereto, and the preliminary hole 170p may have a size (e.g., a diameter) less than the bit size (e.g., the bit diameter) of the drill (e.g., the router drill) used in the cutting process.

Subsequently, the test process of the array printed circuit board 100a may be performed.

In the test process of the array printed circuit board 100a, one side of the array printed circuit board 100a in which the test pad 124 is disposed may be inserted into a test apparatus configured to perform the test process of the array printed circuit board 100a, and the array printed circuit board 100a and the test apparatus may be electrically connected to each other.

In the test process of the array printed circuit board 100a, whether the array printed circuit board 100a operates normally or not, whether the array printed circuit board 100a has a defect or not, or the like may be tested using the test pad 124 and the connection wiring 126. In the test process of the array printed circuit board 100a, the test pad 124 may receive a voltage or a signal from the test apparatus, and may supply the received voltage or signal to the substrate region 10 or the printed circuit board 100 through the connection wiring 126. For example, in the test process of the array printed circuit board 100a, the test pad 124 may be receive a power voltage, a ground voltage, and various signals for a test, and the received voltages or signals to the substrate region 10 or the printed circuit board 100 through the connection wiring 126.

In some implementations, the preliminary hole 170p is formed before the test process of the array printed circuit board 100a. However, the present disclosure are not limited thereto, and the preliminary hole 170p may be formed after the test process of the array printed circuit board 100a.

Subsequently, in FIG. 8, a separation hole 170 configured to disconnect the connection wiring 126 (refer to FIG. 7) may be formed in the substrate region 10. Thereby, the connection wiring 126 may be separated to outer wiring 128 and inner wiring 129 that are spaced apart from each other while interposing the separation hole 170.

The separation hole 170 may entirely pass through the array printed circuit board 100a, the printed circuit board 100, the substrate region 10, or a wiring region 12. Thereby, the separation hole 170 may be easily formed. However, the present disclosure is not limited thereto, and the separation hole 170 may partially pass through the array printed circuit board 100a, the printed circuit board 100, the substrate region 10, or the wiring region 12 in a thickness direction and disconnect the connection wiring 126. Various other modified implementations are possible.

In the process of forming the separation hole 170, the separation hole 170 may be formed using the preliminary hole 170p (refer to FIG. 7). For example, the separation hole 170 may be formed to connect the first preliminary hole 171p (refer to FIG. 7) and the second preliminary hole 172p (refer to FIG. 7). For example, the separation hole 170 may be formed using a drill (e.g., a router drill) used in a cutting process of cutting the array printed circuit board 100a into a plurality of printed circuit boards 100. When the separation hole 170 may be formed using the drill (e.g., the router drill) used in the cutting process, the separation hole 170 may have a size (e.g., a diameter) same as or greater than a bit size (e.g., a bit diameter) of the drill (e.g., the router drill) used in the cutting process. However, the present disclosure is not limited thereto. The process of forming the separation hole 170 may be performed by any of various processes, or a size (e.g., a width or a diameter) of the separation hole 170 may be variously modified.

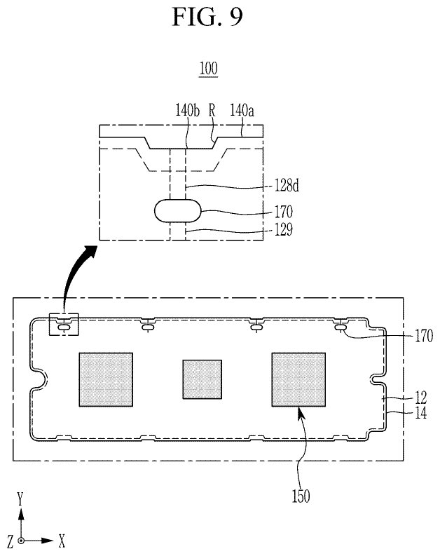

Subsequently, in FIG. 9, a cutting process may be performed. In the cutting process, the array printed circuit board 100a (refer to FIG. 8) may be cut into a plurality of printed circuit boards 100. When the cutting process is performed, a printed circuit board 100 that is formed of at least a portion of the substrate region 10 (refer to FIG. 8) may be formed. A portion (e.g., a first portion) of the outer wiring 128 (refer to FIG. 8) that was disposed in the substrate region 10 may form dummy wiring 128d.

In the cutting process, the array printed circuit board 100a may be cut into the plurality of printed circuit boards 100 using a drill (e.g., a router drill). However, the present disclosure is not limited thereto, and the cutting process may be performed by any of various processes.

In some implementations, the cutting process of cutting the array printed circuit board 100a into the plurality of printed circuit boards 100 is performed after the process of forming the separation hole 170. However, the present disclosure is not limited thereto. In some implementations, the process of forming the separation hole 170 and the cutting process may be performed together, or the process of forming the separation hole 170 may be performed after the cutting process. Various other modified implementations are possible.

According to some implementations, a portion of the wiring 120 (e.g., the dummy wiring 128d) that is exposed on a side surface of the printed circuit board 100 may be separated from a portion (e.g., circuit wiring 122 or the inner wiring 129) of the wiring 120 that is disposed in an inner region of the printed circuit board 100 by an easy process. Accordingly, productivity of the printed circuit board 100 having improved reliability may be improved.

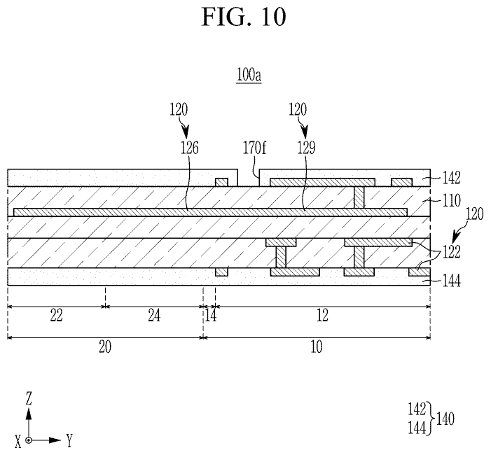

FIG. 10 to FIG. 12 are cross-sectional views showing an example of a manufacturing method of a printed circuit board according to some implementations. FIG. 10 to FIG. 12 illustrate a portion corresponding to FIG. 4 or FIG. 6 according to some implementations. To the extent that an element is not described in detail below, it may be understood that the element is at least similar to a corresponding element that has been described with reference to FIG. 7 to FIG. 9. A portion which is not described in the above will be described in detail.

In FIG. 10 to FIG. 12, a manufacturing method of a printed circuit board 100 may include a process of forming an array printed circuit board 100a, a test process of the array printed circuit board 100a, and a process of forming a separation hole 170 and cutting the array printed circuit board 100a into an individual printed circuit board 100.

First, in FIG. 10, a process of forming an array printed circuit board 100a may be performed, and a test process of the array printed circuit board 100a may be performed.

In the process of forming the array printed circuit board 100a, the array printed circuit board 100a may be formed. The array printed circuit board 100a may include a plurality of substrate regions 10 in which a plurality of substrate regions 10 are disposed, respectively, a peripheral region 20 that connects the plurality of substrate regions 10, a test pad 12 that is disposed in the peripheral region 20, and connection wiring 126 that electrically connects the test pad 124 and the substrate region 10. The connection wiring 126 may extend from the test pad 124 and extend to an inside of the substrate region 10 (e.g., an inside of a wiring region 12) through a bridge portion 24.

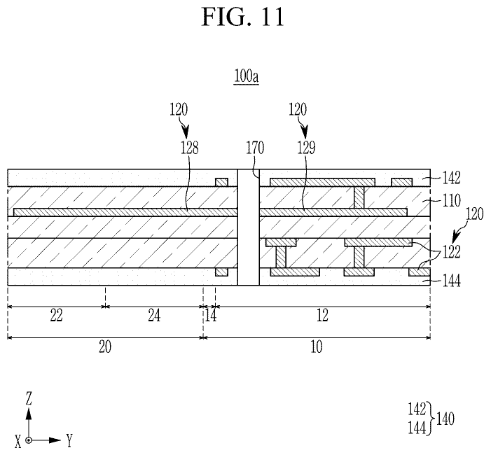

In some implementations, in the process of forming the array printed circuit board 100a, a preliminary mark may be formed in a portion corresponding to at least a portion of a separation hole 170 (refer to FIG. 11). For example, the array printed circuit board 100a may include an opening 107f as the preliminary mark. The opening 107f may be formed by removing a portion of a protection layer 140 (e.g., a first protection layer 142 or a second protection layer 144). By the opening 107f of the protection layer 140, a position where the separation hole 170 will be disposed may be easily recognized or determined in a process of forming the separation hole 170. When the connection wiring 126 may be disposed in an inner portion of the array printed circuit board 100a, by marking the position of the separation hole 170 using the preliminary mark (e.g., the opening 107f of the protection layer 140), the position where the separation hole 170 will be disposed may be easily recognized or expected.

In some implementations, the opening 107f may include a first opening and a second opening disposed at opposite sides of the connection wiring 126. In some implementations, the opening 107f may be entirely formed in a portion where the separation hole 170 will be disposed. However, the present disclosure is not limited thereto. The opening 107f may include at least one of the first opening and the second opening, the opening 107f may further include an additional opening other than the first opening and the second opening, or the opening 107f may be formed to correspond to a portion where the separation hole 170 will be disposed.

In FIG. 10, the opening 107f is formed in the first protection layer 142. In some implementations, the opening 107f may be formed in the second protection layer 144. For example, the opening 107 may be formed at least at a surface where the cutting process is performed. When the cutting process is performed at an upper surface of the array printed circuit board 100a, an opening 107f may be formed in a first protection layer 142 in a printed circuit board 100 disposed in a first substrate region 10a illustrated in FIG. 1, and an opening 107f may be formed in a second protection layer 144 in a printed circuit board 100 disposed in a second substrate region 10b illustrated in FIG. 1. When the cutting process is performed at a lower surface of the array printed circuit board 100a, an opening 107f may be formed in a second protection layer 142 in a printed circuit board 100 disposed in a first substrate region 10a illustrated in FIG. 1, and an opening 107f may be formed in a first protection layer 142 in a printed circuit board 100 disposed in a second substrate region 10b illustrated in FIG. 1. In some implementations, the opening 107f may be formed in each of the first protection layer 142 and the second protection layer 144.

The opening 107f may have a size (e.g., a diameter) same as or greater than a bit size (e.g., a bit diameter) of a drill (e.g., a router drill) used in a cutting process.

Subsequently, the test process of the array printed circuit board 100a may be performed.

In some implementations, the opening 107f of the protection layer 140 is formed before the test process of the array printed circuit board 100a. However, the present disclosure is not limited thereto, and the opening 107f of the protection layer 140 may be formed after the test process of the array printed circuit board 100a.

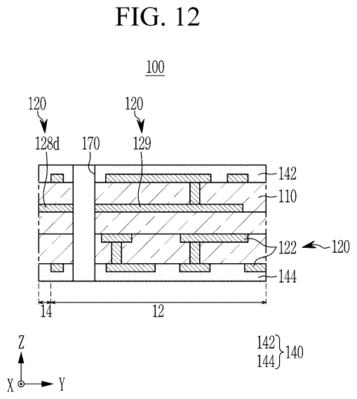

In some implementations, the opening 107f of the preliminary mark is formed by removing a portion of the protection layer 140. Thereby, presence or absence of the protection layer 140 may be easily recognized or determined, a portion where the separation hole 170 will be disposed may be easily recognized or expected. However, the present disclosure is not limited thereto. In some implementations, the opening 107f of the preliminary mark may be formed by removing a portion of a layer included in the array printed circuit board 100a or a printed circuit board 100 (refer to FIG. 12).

Subsequently, in FIG. 11, a separation hole 170 configured to disconnect the connection wiring 126 (refer to FIG. 10) may be formed in the substrate region 10. Thereby, the connection wiring 126 may be separated to outer wiring 128 and inner wiring 129 that are spaced apart from each other while interposing the separation hole 170.

In the process of forming the separation hole 170, the separation hole 170 may be formed using the opening 170f (refer to FIG. 10) of the protection layer 140. For example, the separation hole 170 may be formed using a drill (e.g., a router drill) used in a cutting process of cutting the array printed circuit board 100a into a plurality of printed circuit boards 100. When the separation hole 170 may be formed using the drill (e.g., the router drill) used in the cutting process, the separation hole 170 may have a size (e.g., a diameter) same as or greater than a bit size (e.g., a bit diameter) of the drill (e.g., the router drill) used in the cutting process. However, the present disclosure is not limited thereto. The process of forming the separation hole 170 may be performed by any of various processes, or a size (e.g., a width or a diameter) of the separation hole 170 may be variously modified.

Subsequently, in FIG. 12, a cutting process may be performed. In the cutting process, the array printed circuit board 100a (refer to FIG. 11) may be cut into a plurality of printed circuit boards 100. When the cutting process is performed, a printed circuit board 100 that is formed of at least a portion of the substrate region 10 (refer to FIG. 11) may be formed. A portion (e.g., a first portion) of the outer wiring 128 (refer to FIG. 11) that was disposed in the substrate region 10 may form dummy wiring 128d.

In the cutting process, the array printed circuit board 100a may be cut into the plurality of printed circuit boards 100 using a drill (e.g., a router drill). However, the present disclosure is not limited thereto, and the cutting process may be performed by any of various processes.

In some implementations, the cutting process of cutting the array printed circuit board 100a into the plurality of printed circuit boards 100 is performed after the process of forming the separation hole 170. However, the present disclosure is not limited thereto. In some implementations, the process of forming the separation hole 170 and the cutting process may be performed together, or the process of forming the separation hole 170 may be performed after the cutting process. Various other modified implementations are possible.

According to some implementations, a portion of the wiring 120 (e.g., the dummy wiring 128d) that is exposed on a side surface of the printed circuit board 100 may be separated from a portion (e.g., circuit wiring 122 or the inner wiring 129) of the wiring 120 that is disposed in an inner region of the printed circuit board 100 by an easy process. Accordingly, productivity of the printed circuit board 100 having improved reliability may be improved.

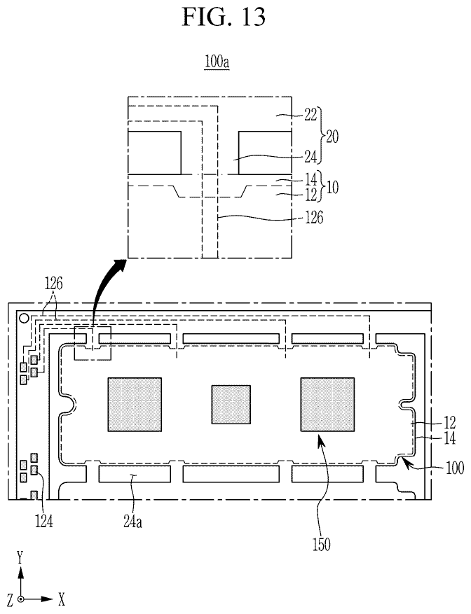

FIG. 13 to FIG. 15 are plan views showing an example of a manufacturing method of a printed circuit board according to some implementations. FIG. 13 to FIG. 15 illustrate a portion corresponding to FIG. 3 or FIG. 5 according to some implementations. To the extent that an element is not described in detail below, it may be understood that the element is at least similar to a corresponding element that has been described with reference to FIG. 7 to FIG. 12. A portion which is not described in the above will be described in detail.

In FIG. 13 to FIG. 15, a manufacturing method of a printed circuit board 100 may include a process of forming an array printed circuit board 100a, a test process of the array printed circuit board 100a, and a process of forming a separation hole 170 and cutting the array printed circuit board 100a into an individual printed circuit board 100.

First, in FIG. 13, a process of forming an array printed circuit board 100a may be performed, and a test process of the array printed circuit board 100a may be performed.

In the process of forming the array printed circuit board 100a, the array printed circuit board 100a may be formed. The array printed circuit board 100a may include a plurality of substrate regions 10 in which a plurality of substrate regions 10 are disposed, respectively, a peripheral region 20 that connects the plurality of substrate regions 10, a test pad 12 that is disposed in the peripheral region 20, and connection wiring 126 that electrically connects the test pad 124 and the substrate region 10. The connection wiring 126 may extend from the test pad 124 and extend to an inside of the substrate region 10 (e.g., an inside of a wiring region 12) through the bridge portion 24.

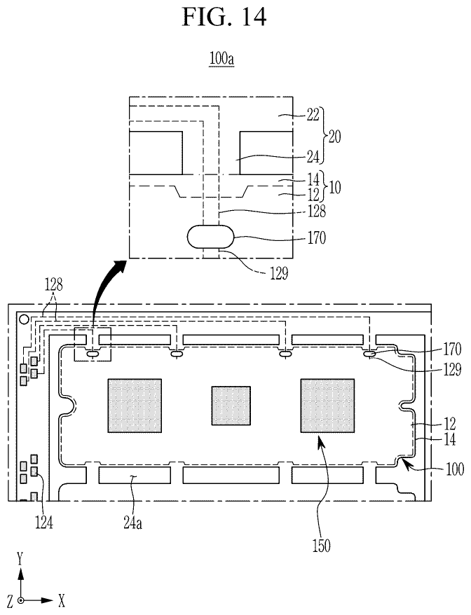

In some implementations, in the process of forming the array printed circuit board 100a, a preliminary mark for forming a separation hole 170 (refer to FIG. 14) may not be formed.

Subsequently, in FIG. 14, a separation hole 170 configured to disconnect the connection wiring 126 (refer to FIG. 13) may be formed in the substrate region 10. Thereby, the connection wiring 126 may be separated to outer wiring 128 and inner wiring 129 that are spaced apart from each other while interposing the separation hole 170.

In the process of forming the separation hole 170, the separation hole 170 may be formed using laser. When the laser is used, the separation hole 170 may have a small size (e.g., a small width). Further, a preliminary mark for forming the separation hole 170 may be omitted, and a manufacturing process may be simplified. However, the present disclosure is not limited thereto, and the process of forming the separation hole 170 may be performed by any of various processes.

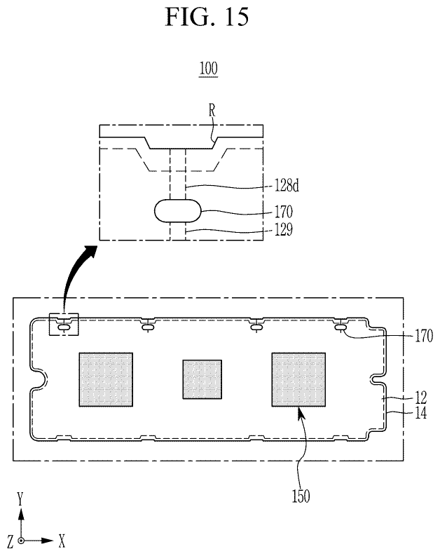

Subsequently, in FIG. 15, a cutting process may be performed. In the cutting process, the array printed circuit board 100a (refer to FIG. 14) may be cut into a plurality of printed circuit boards 100. When the cutting process is performed, a printed circuit board 100 that is formed of at least a portion of the substrate region 10 (refer to FIG. 14) may be formed. A portion (e.g., a first portion) of the outer wiring 128 (refer to FIG. 14) that was disposed in the substrate region 10 may form dummy wiring 128d.

In the cutting process, the array printed circuit board 100a may be cut into the plurality of printed circuit boards 100 using a drill (e.g., a router drill). However, the present disclosure is not limited thereto, and the cutting process may be performed by any of various processes.

In some implementations, the cutting process of cutting the array printed circuit board 100a into the plurality of printed circuit boards 100 is performed after the process of forming the separation hole 170. However, the present disclosure is not limited thereto. In some implementations, the process of forming the separation hole 170 and the cutting process may be performed together, or the process of forming the separation hole 170 may be performed after the cutting process. Various other modified implementations are possible.

According to some implementations, a portion of the wiring 120 (e.g., the dummy wiring 128d) that is exposed on a side surface of the printed circuit board 100 may be separated from a portion (e.g., circuit wiring 122 or the inner wiring 129) of the wiring 120 that is disposed in an inner region of the printed circuit board 100 by an easy process. Accordingly, productivity of the printed circuit board 100 having improved reliability may be improved.

Hereinafter, in FIG. 16, an array printed circuit board will be described in detail. To the extent that an element is not described in detail below, it may be understood that the element is at least similar to a corresponding element that has been described elsewhere within the present disclosure. A portion which is not described in the above will be described in detail.

FIG. 16 is a partial plan view showing an example of an array printed circuit board according to some implementations. FIG. 16 illustrates a portion corresponding to a portion in an enlarged circle of FIG. 3 according to some implementations.

In FIG. 16, a plurality of outer wirings 128 may be disposed in one bridge portion 24, and a plurality of inner wirings 129 may be disposed to correspond to the plurality of outer wirings 128, respectively. The separation hole 170 may separate the plurality of outer wirings 128 and the plurality of inner wirings 129 in one bridge portion 24.

For example, in one bridge portion 24, a third outer wiring 128e and a fourth outer wiring 128f may be disposed at a first side of the separation hole 170, and a third inner wiring 129e and a fourth inner wiring 129f may be disposed at a second side of the separation hole 170. The third outer wiring 128e and the third inner wiring 129e may be formed of remained portions of a third connection wiring, and the fourth outer wiring 128f and the fourth inner wiring 129f may be formed of remained portions of a fourth connection wiring remain. By one separation hole 170, the third outer wiring 128e and the third inner wiring 129e, and the fourth outer wiring 128f and the fourth inner wiring 129f may be disconnected. Thereby, by a simple process, a plurality of connection wirings (e.g., the third connection wiring and the fourth connection wiring) may be disconnected.

A width of the separation hole 170 may be greater than a sum of a line width of the third outer wiring 128e and a line width of the fourth outer wiring 128f. The width of the separation hole 170 may be greater than a sum of the line width of the third outer wiring 128e, the line width of the fourth outer wiring 128f, and an interval between the third outer wiring 128e and the fourth outer wiring 128f. In some implementations, the width of the separation hole 170 may be greater than a sum of a line width of the third inner wiring 129e and a line width of the fourth inner wiring 129f. The width of the separation hole 170 may be greater than a sum of the line width of the third inner wiring 129e, the line width of the fourth inner wiring 129f, and an interval between the third inner wiring 129e and the fourth inner wiring 129f. Thereby, the third outer wiring 128e and the third inner wiring 129e may be stably separated, and the fourth outer wiring 128f and the fourth inner wiring 129f may be stably separated.

In a printed circuit board formed by a cutting process of cutting an array printed circuit board into an individual printed circuit board, in a portion corresponding to one bridge portion 24, a plurality of dummy wirings may be disposed at the first side of the separation hole 170, and a plurality of inner wirings 129 that correspond to the plurality of dummy wirings, respectively, may be disposed at the second side of the separation hole 170. The plurality of dummy wirings and the plurality of inner wirings 129 may include a same material, and may be disposed to correspond to each other on the first side and the second side of the separation hole 170. In a portion of the dummy wiring and a portion of the inner wiring 129 that face each other, the dummy wiring and the inner wiring 129 may have a same line width.

However, the present disclosure is not limited thereto. In some implementations, a plurality of separation holes 170 may be provided to correspond to the plurality of outer wirings 128 or the plurality of inner wirings 129, respectively, in one bridge portion 24 of the array printed circuit board. In this instance, in a printed circuit board, in a portion corresponding to one bridge portion 24, a plurality of separation holes 170 may be provided to correspond to the plurality of dummy wirings or the plurality of inner wirings 129, respectively.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An array printed circuit board, comprising:
a plurality of substrate regions in which a plurality of printed circuit boards are disposed, respectively; and
a peripheral region connected to the plurality of substrate regions,
wherein at least one substrate region of the plurality of substrate regions comprises a separation hole,
wherein the at least one substrate region and the peripheral region comprise wiring, wherein the wiring comprises one or more wiring layers, and
wherein the wiring comprises outer wiring that includes a first portion between an edge of the at least one substrate region and a first side of the separation hole that is adjacent to the edge of the at least one substrate region.

2. The array printed circuit board of claim 1,
wherein the at least one substrate region includes a wiring region and an edge region outside the wiring region,
wherein the wiring region comprises circuit wiring of a first printed circuit board, and
wherein the wiring region comprises the separation hole.

3. The array printed circuit board of claim 2, wherein the circuit wiring comprises outside wiring that is outside of the separation hole in a plan view of the array printed circuit board.

4. The array printed circuit board of claim 1, wherein the outer wiring is electrically insulated from another portion of the wiring located in the at least one substrate region.

5. The array printed circuit board of claim 1,
wherein the wiring includes inner wiring that is at a second side of the separation hole,
wherein the second side of the separation hole is opposite to the first side of the separation hole, and
wherein the inner wiring is spaced apart from the outer wiring by the separation hole.

6. The array printed circuit board of claim 5,
wherein the outer wiring and the inner wiring include a same material,
wherein the outer wiring includes at least one outer wire element arranged on the first side of the separation hole,
wherein the inner wiring includes at least one inner wire element arranged on the second side of the separation hole, and
wherein the at least one outer wire element is across from the at least one inner wire element, respectively.

7. The array printed circuit board of claim 1, wherein the separation hole comprises a shape that is elongated in a first direction parallel to the edge of the at least one substrate region to which the separation hole is adjacent or that is elongated in a second direction that intersects a path along which the first portion of the outer wiring is elongated.

8. The array printed circuit board of claim 1,
wherein a length of the separation hole in a direction parallel to the edge of the at least one substrate region to which the separation hole is adjacent is greater than a line width of the outer wiring, and
wherein a ratio of the length of the separation hole to the line width of the outer wiring is in a range of 1.2 to 3.

9. The array printed circuit board of claim 1,
wherein the at least one substrate region comprises a plurality of separation holes, and
wherein at least two separation holes of the plurality of separation holes have different lengths.

10. A printed circuit board, comprising:
a stacking structure that includes an insulation layer and wiring, wherein the wiring comprises a plurality of wiring layers; and
a separation hole configured to separate at least one wiring layer of the plurality of wiring layers,
wherein the wiring comprises dummy wiring between an edge of the stacking structure and a first side of the separation hole adjacent to the edge of the stacking structure.

11. The printed circuit board of claim 10, comprising:
an electronic element on the stacking structure,
wherein the wiring comprises circuit wiring electrically connected to the electronic element,
wherein the stacking structure comprises a wiring region and an edge region outside the wiring region,
wherein the circuit wiring is in the wiring region,
wherein at least a portion of the dummy wiring is in the edge region, and
wherein the separation hole is in the wiring region.

12. The printed circuit board of claim 11, wherein, in a plan view of the printed circuit board, the circuit wiring comprises outside wiring outside the separation hole.

13. The printed circuit board of claim 10, wherein the dummy wiring is electrically insulated from another portion of the wiring.

14. The printed circuit board of claim 10, wherein the wiring comprises inner wiring at a second side of the separation hole,
wherein the second side of the separation hole is opposite to the first side of the separation hole, and
wherein the inner wiring is spaced apart from the dummy wiring by the separation hole.

15. The printed circuit board of claim 14,
wherein the dummy wiring and the inner wiring comprise a same material,
wherein the dummy wiring includes at least one dummy wire element arranged on the first side of the separation hole,
wherein the inner wiring includes at least one inner wire element arranged on the second side of the separation hole, and
wherein the at least one dummy wire element is across from the at least one inner wiring element arranged on the second side of the separation hole, respectively.

16. The printed circuit board of claim 10, wherein the separation hole comprises a shape that is elongated in a first direction parallel to the edge of the stacking structure to which the separation hole is adjacent or that is elongated in a second direction that intersects a path along which the dummy wiring is elongated.

17. A manufacturing method of a printed circuit board, comprising:
forming an array printed circuit board, wherein the array printed circuit board comprises
a plurality of substrate regions in which a plurality of printed circuit boards are disposed, respectively,
a peripheral region configured to connect the plurality of substrate regions,
a test pad in the peripheral region, and
connection wiring that electrically connects the test pad and at least one substrate region of the plurality of substrate regions;
testing the array printed circuit board using the test pad and the connection wiring;
forming a separation hole; and
cutting the array printed circuit board,
wherein the separation hole is configured to disconnect the connection wiring from wiring in the at least one substrate region.

18. The manufacturing method of claim 17, wherein, forming of the array printed circuit board comprises forming a preliminary mark in the at least one substrate region.

19. The manufacturing method of claim 18,
wherein the preliminary mark is a preliminary separation hole or an opening, and
wherein forming the preliminary separation hole or the opening comprises removing a portion of a layer of the array printed circuit board.

20. The manufacturing method of claim 17, wherein forming the separation hole comprises using a router drill or laser.
